(19) United States
(12) Patent Application Publication
(10) Pub. No.: US 2010/0141247 A1
(43) Pub. Date: Jun. 10, 2010

(54) CONSTANT CURRENT METAL DETECTOR WITH DRIVEN TRANSMIT COIL

(75) Inventor: Bruce Halcro CANDY, Basket Range (AU)

Correspondence Address: Beyer Law Group LLP, P.O. BOX 1687, Cupertino, CA, 95015-1687, US

(73) Assignee: MINELAB ELECTRONICS PTY LIMITED, Torrensville (AU)

(21) Appl. No.: 12/621,427

(22) Filed: Nov. 18, 2009

Related U.S. Application Data
(63) Continuation of application No. PCT/AU2009/000836, filed on Jun. 29, 2009.

(30) Foreign Application Priority Data
Jun. 27, 2008 (AU) 2008903280
Aug. 29, 2008 (AU) 2008904489
Feb. 18, 2009 (AU) 2009900687

(51) Int. Cl. G01R 33/12; G01V 3/10

(52) U.S. Cl. 324/239; 324/329

(57) ABSTRACT

A metal detector transmitting, through a transmit coil, a repeating transmit signal cycle, which includes at least one receive period and at least one non-zero transmit coil reactive voltage period; and sensing a current in the transmit coil during at least one receive period to control a magnitude and/or duration of the at least one non-zero transmit coil reactive voltage period such that the average value of the current during at least one receive period of every repeating transmit signal cycle is substantially constant, and the current during at least one receive period is substantially independent of the inductance of the transmit coil.

### CROSS REFERENCE TO RELATED APPLICATIONS

This application is a continuation of International Application No. PCT/AU2009/000836, filed on Jun. 29, 2009, which is incorporated herein by reference for all purposes.

### TECHNICAL FIELD

This invention relates to metal detectors that are time-domain detectors.

### INCORPORATION BY REFERENCE

The following documents are referred to in the present specification: U.S. Pat. No. 5,576,624 entitled ‘Pulse induction time domain metal detector’; U.S. Pat. No. 6,636,044 entitled ‘Ground mineralization rejecting metal detector (receive signal weighting)’; U.S. Pat. No. 6,653,838 entitled ‘Ground mineralization rejecting metal detector (transmit signal)’; U.S. Pat. No. 6,686,742 entitled ‘Ground mineralization rejecting metal detector (power saving)’; US Patent Application No. 2008/0048661 entitled ‘Rectangular-wave transmitting metal detector’; Australian Provisional Patent Application No. 2006903737 entitled ‘Metal detector having constant reactive transmit voltage applied to a transmit coil’; Australian Provisional Patent Application No. 2007906175 entitled ‘Metal detector with improved magnetic response application’; International Patent Application No. PCT/AU2007/001507 entitled ‘Metal detector with improved magnetic soil response cancellation’; International Patent Publication No. WO 2005/047932 entitled ‘Multi-frequency metal detector having constant reactive transmit voltage applied to a transmit coil’. The entire content of each of these documents is hereby incorporated by reference.

### BACKGROUND

The general forms of most metal detectors which interrogate soils are either hand-held battery operated units, conveyor-mounted units, or vehicle-mounted units. Examples of hand-held battery operated units include detectors used to locate gold, explosive land mines or ordnance, coins and treasure. An example of a conveyor-mounted unit includes a fine gold detector used in ore mining operations, and an example of a vehicle-mounted unit includes a detector to locate buried land mines.

These electronic metal detectors usually consist of transmit electronics generating a repeating transmit signal cycle, which is applied to an inductor, a transmit coil, which transmits a resulting alternating magnetic field.

Time domain metal detectors usually include switching electronics within the transmit electronics, which switches various voltages from various power sources to the transmit coil for various periods in a repeating transmit signal cycle.

Metal detectors contain receive electronics which processes a receive magnetic field to produce an indicator output, the indicator output at least indicating the presence of at least some metal targets under the influence of the transmit magnetic field.

Traditional pulse induction metal detectors are time domain detectors, having a plurality of switches for switching at least first and second voltages from power sources, and zero volts for various durations, to generate a repeating transmit signal cycle with a fundamental frequency usually being in the range from tens of Hertz to several kiloHertz. The second voltage from a second power source is usually a low negative voltage, −6V for example, and is switched to the transmit coil during an low-voltage period, immediately followed by a back-emf period (a high-voltage period) of high first voltage switched to a first power source usually via a diode whilst forward biased, for example +180V, and a zero-voltage period immediately following the high-voltage period. The transmit electronics presents a low source impedance to the transmit coil during the low-voltage period and back-emf period, assuming that the coil is connected to the first power source, but presents a high impedance during the period in which the critically damped decay of the back-emf occurs, and during the zero-voltage period when no transmit coil current flows and a magnetic signal is received, by the receive electronics. During these high impedance periods, the said switching electronics output impedance is usually a function of the capacitance of the switching electronics in parallel with a resistor (e.g. 500Ω) whose value is usually selected to critically damp the self-resonance of the transmit coil connected to transmitting electronics. As this period of relatively high impedance commences with a decay of a pulse induction back-emf period, the received signal will contain a reactive component (X) during this decay period. Hence, to avoid contaminating the receive signal with this X component, usually most, if not all, of the receive signal processing of sampling, or synchronous demodulation, is delayed so as to occur during the period of zero-voltage after the back-emf has decayed.

For the sake of simplicity, assume both conventional pulse induction transmit and receive coils have a critically damped time constant of τ. The transient output from the receive coil, in the ideal case of zero capacitive coupling but finite mutual inductance between the transmit and receive coil, is of the form

ae^{-t/τ}+bte^{-t/τ} (1)

where the coefficient a depends on the duration and magnitude of the back-emf, and the coefficient b is due to the decaying damped transmit reactive voltage following the back-emf.

Many metal targets, such as small gold nuggets and fine gold chains, have short decay periods. The delay of the processing (sampling or synchronous demodulation) of the receive signal after the back-emf periods results in reduced sensitivity to these fast decay targets. The delay cannot be made too short because contamination of the receive signal with the X occurs if the receive processing occurs when (1) is significant. Hence, if (1) can be reduced, then targets with faster time constants targets can be detected without contamination with X.

Pulse induction metal detectors are not power efficient, even with remedial components described in U.S. Pat. No. 6,686,742. For example, some pulse induction metal detectors include a diode in series with the transmit coil and switching electronics, reducing power efficiency. As well, the transmit coil damping resistor will necessarily dissipate some power, further reducing the efficiency.

It is therefore an aim of this invention to reduce, or eliminate, the above problems, or at least offer an alternative arrangement for a metal detector.

WO 2008/006178 A1 discloses a metal detector which produces a constant reactive voltage throughout most of its repeating transmit signal cycle, which is unchanged when the inductance of the transmit coil is modulated by the transmit coil passing by magnetically permeable soils. Reception occurs during periods when the transmit coil current is finite and the reactive transmit coil voltage is zero.

Whilst the present invention also produces periods of zero transmit reactive voltages with finite transmit coil current, as the coil inductance varies as it is passed over magnetically permeable soils, the magnitudes of transmit coil current during zero reactive voltage periods and/or periods of non-zero reactive transmit coil voltage are modulated by the transmit coil inductance. Whilst WO 2008/006178 A1 discloses a theoretical optimal condition, the invention described herein offers a practical compromise which nevertheless produces satisfactory results.

### BRIEF SUMMARY OF THE INVENTION

In a broad aspect of the invention there is provided a metal detector used for detecting a metallic target including: a) transmit electronics having a plurality of switches for generating a repeating transmit signal cycle, the repeating transmit signal cycle including at least one receive period and at least one non-zero transmit coil reactive voltage period; b) a transmit coil having an inductance connected to the transmit electronics for receiving the repeating transmit signal cycle and generating a transmitted magnetic field; c) a receive coil for receiving a received magnetic field during at least one receive period and providing a received signal induced by the received magnetic field; d) at least one negative feedback loop for sensing a current in the transmit coil during at least one receive period to provide a control signal, the control signal controlling a magnitude and/or duration of the at least one non-zero transmit coil reactive voltage period such that the average value of the current during at least one receive period of every repeating transmit signal cycle is substantially constant, and the current during at least one receive period is substantially independent of the inductance of the transmit coil; and e) receive electronics connected to the receive coil for processing the received signal during at least one receive period to produce an indicator output signal, the indicator output signal including a signal indicative of the presence of a metallic target in the soil.

In one form, the repeating transmit signal cycle includes a high-voltage period, the high-voltage period is a non-zero transmit coil reactive voltage period, and is followed by a low-voltage period and at least another period of non-zero transmit coil reactive voltage period; the low-voltage period is the said receive period, and the average value of the transmit coil current during the low-voltage period of every repeating transmit signal cycle is non-zero.

In one form, the repeating transmit signal cycle includes a low-voltage period, the low-voltage period followed by a high-voltage period, and the high-voltage period followed by a zero-voltage period; the zero-voltage period is the said receive period, and the average value of the transmit coil current during the zero-voltage period of every repeating transmit signal cycle is zero.

In one form, the repeating transmit signal cycle includes at least two receive periods, a first receive period and a second receive period, the average value of the current during the first receive period is substantially different from the average value of the current during the second receive period.

In one form, the repeating transmit signal cycle includes at least two different sequences, a first sequence and a second sequence, the first sequence including a first high-voltage period and a first low-voltage period, and the second sequence including a second high-voltage period and a second low-voltage period, wherein the first and second low-voltage periods are the first and second receive periods respectively, and the second sequence is opposite in polarity to the first sequence.

In one form, the current waveform of the repeating transmit signal cycle is substantially a square wave.

In one form, the repeating transmit signal cycle includes at least two different sequences, a first sequence and a second sequence, the first sequence including a first low-voltage period, a first high-voltage period and a first zero-voltage period, and the second sequence including a second low-voltage period, a second high-voltage period and a second zero-voltage period, wherein the first and second zero-voltage periods are first and second receive periods respectively, and at least one of the first low-voltage period, the first high-voltage period and the first zero-voltage period, differs from the respective second low-voltage period, second high-voltage period and second zero-voltage period in at least voltage and/or duration.

In an embodiment of the immediate preceding form, the first low-voltage period is of opposite polarity to the second low-voltage period, and the first high-voltage period is of opposite polarity to the second high-voltage period.

In one form, an output impedance of the transmit electronics connected to the transmit coil is less than three times an equivalent series resistance of the transmit coil at least immediately after the beginning of the receive period.

In one form, the processing of the received signal by the receive electronics includes sampling and/or synchronous demodulation followed by averaging and/or low pass filtering to substantially remove signals with frequency of the repeating transmit signal cycle, to produce a receive reactive signal and a receive resistive signal, the receive reactive signal being responsive to non-dissipative components coupling between the transmit magnetic field and the receive magnetic field, and the receive resistive signal being responsive to dissipative components coupling between the transmit magnetic field and the receive magnetic field,

wherein the receive reactive signal is differentiated with respect to time to give a differentiated receive reactive signal; a first portion of the differentiated receive reactive signal is subtracted from the receive resistive signal to give a modified receive resistive signal, the said first portion is selected to approximately cancel any component of the receive resistive signal proportional to the differentiated receive reactive signal; and the modified receive resistive signal is further processed by the receive electronics to produce an indicator signal.

In one form, the absolute average voltage value across the transmit coil of the high-voltage period is at least about three times an absolute average voltage value across the transmit coil of the low-voltage period.

In one form, the average absolute value of a voltage during a high-voltage period is within the range of about 10 volts to about 400 volts.

In one form, the average absolute value of a voltage during a low-voltage period is within the range of about 0.1 volts to about 15 volts.

A detailed description of one or more embodiments of the invention is provided below, along with accompanying figures that illustrate, by way of example the principles of the invention. While the invention is described in connection with such embodiments, it should be understood that the invention is not limited to any embodiment. On the contrary, the scope of the invention is limited only by the appended claims and the invention encompasses numerous alternatives, modifications, and equivalents. For the purpose of example, numerous specific details are set forth in the following description in order to provide a thorough understanding of the present invention. The present invention may be practised according to the claims without some or all of these specific details. For the purpose of clarity, technical material that is known in the technical fields related to the invention has not been described in detail so that the present invention is not unnecessarily obscured.

Throughout this specification and the claims that follow, unless the context requires otherwise, the words ‘comprise’ and ‘include’ and variations such as ‘comprising’ and ‘including’ will be understood to imply the inclusion of a stated integer or group of integers but not the exclusion of any other integer or group of integers.

The term “average” in the context of this description of embodiments could include a meaning generally understood by a person skilled in the art and could include a robust average where the calculation for average is not biased by outliers. Also, more technically, the term “average” could include a robust estimator of the central tendency or location parameter.

The term “constant” in this context of this description of embodiments means an approximately unvarying magnitude about a predetermined value. This predetermined value could be controlled and adjusted depending on different applications but would normally remains unchanged or “constant” during a use of the embodiment described.

The reference to any prior art in this specification is not, and should not be taken as an acknowledgment or any form of suggestion that such prior art forms part of the common general knowledge of the technical field.

### BRIEF DESCRIPTION OF THE DRAWINGS

To assist with the understanding of this invention, reference will now be made to the drawings:

FIG. 1 depicts a general block diagram of a metal detector with a negative feedback loop to monitor the transmit coil current.

FIG. 2 depicts an example waveform of the repeating transmit signal cycle (a) with its corresponding transmit coil current square-wave (b); being one of the possible transmit waveforms generated by the electronic circuit depicted in block diagram in FIG. 3.

FIG. 3 depicts a block electronic circuit diagram of one embodiment of the invention with an electronic system capable of producing a repeating transmit signal cycle including low-voltage periods of constant current and zero reactive voltage.

FIG. 4 depicts a block electronic circuit diagram of one embodiment of the invention with an electronic system capable of continuously producing a pulse induction-like waveform from a low impedance repeating transmit signal cycle source.

FIG. 5 depicts an example waveform of the repeating transmit signal cycle, which is a pulse induction-like waveform.

FIG. 6 depicts another example waveform of the repeating transmit signal cycle, which is a multi-voltage and multi-period waveform.

FIG. 7 depicts another example waveform of the repeating transmit signal cycle, which is a pulse induction-like symmetric bipolar system waveform.

FIG. 8 depicts an alternative block electronic circuit diagram of the coil switching circuit suitable for bipolar transmission, such as the generation of the waveform shown in FIG. 7 for transmission.

### DETAILED DESCRIPTION OF THE INVENTION

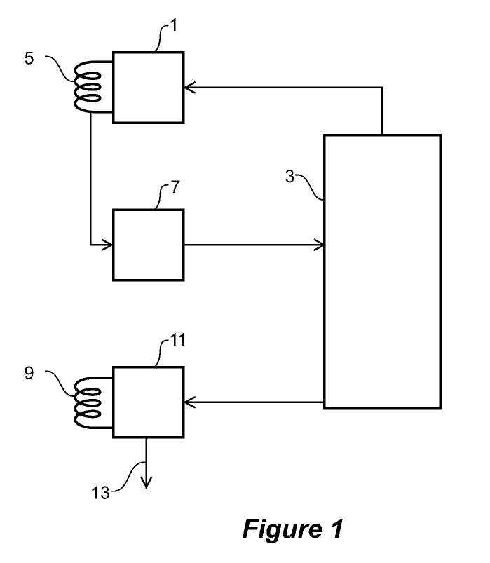

FIG. 1 is a block diagram showing the main parts of a metal detector. Transmit electronics 1 contains switches, and might also include linear elements controlled by timing electronics 3 to generate a repeating transmit signal cycle into a transmit coil 5 connected to the transmit electronics 1. The transmit coil 5 generates, in response to the repeating transmit signal cycle from transmit electronics 1, a transmitted magnetic field, which is directed towards a soil medium (not shown), in which there may be metal targets. The physical form of the coil is well known to those skilled in the art and can take many forms. A negative feedback loop amplifier 7 senses the current in the transmit coil 5 to provide a control signal to timing electronics 3 to control the duration and/or magnitude of the repeating transmit signal cycle.

A receive coil 9 which is located in the vicinity of the soil medium is connected to receive electronics 11. Transmit coil 5 and receive coil 9 may be the same coil. The received magnetic field induces a received signal in the receive coil 9 (an electromotive force or emf signal) which is processed by receive electronics 11 to generate an indicator output signal 13 to indicate the presence of metals affected by the transmitted magnetic field.

Some of the functions of the receive electronics 11, such as those performed by the synchronous demodulators and any further processing, may be implemented in either or both software (such as a Digital Signal Processor (DSP) programmed into an Application Specific Integrated Circuit) or hardware such as an analogue circuitry and is typically provided as a combination of software and hardware.

A basic form of the repeating transmit signal cycle of the present invention includes at least a non-zero transmit coil reactive voltage period and at least a receive period. The transmit coil reactive voltage is related to the transmit coil current through the relationship v=Ldi/dt, where v is the transmit coil reactive voltage, i is the transmit coil current and L is the effective inductance of the transmit coil. Hence, a non-zero transmit coil reactive voltage implies a changing (non-constant) current, if the inductance of the coil, L, remains constant.

The applied voltage, u, equals Ldi/dt+Ri, where R is the effective transmit coil resistance. Note that it is obvious to a person skilled in the art that reactive voltage is not equal to the applied voltage across the transmit coil.

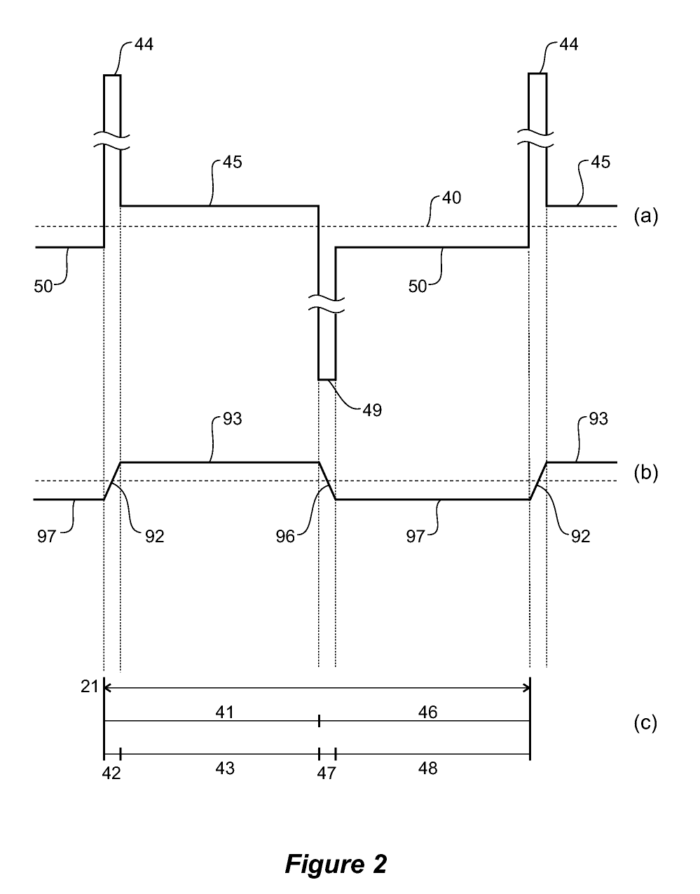

FIG. 2 shows an embodiment of the repeating transmit signal cycle, where the repeating transmit signal cycle includes two different sequences, the first sequence 41 including a first high-voltage period 42 followed by a first low-voltage period 43, and the second sequence 46 including a second high-voltage period 47 followed by a second low-voltage period 48. The first and second low-voltage periods, 43 and 48, are the first and second receive periods respectively, and the second sequence 46 is opposite in polarity to the first sequence 41. FIGS. 2 (a) and 2 (b) show the applied voltages and currents, respectively, of the repeating transmit signal cycle 21.

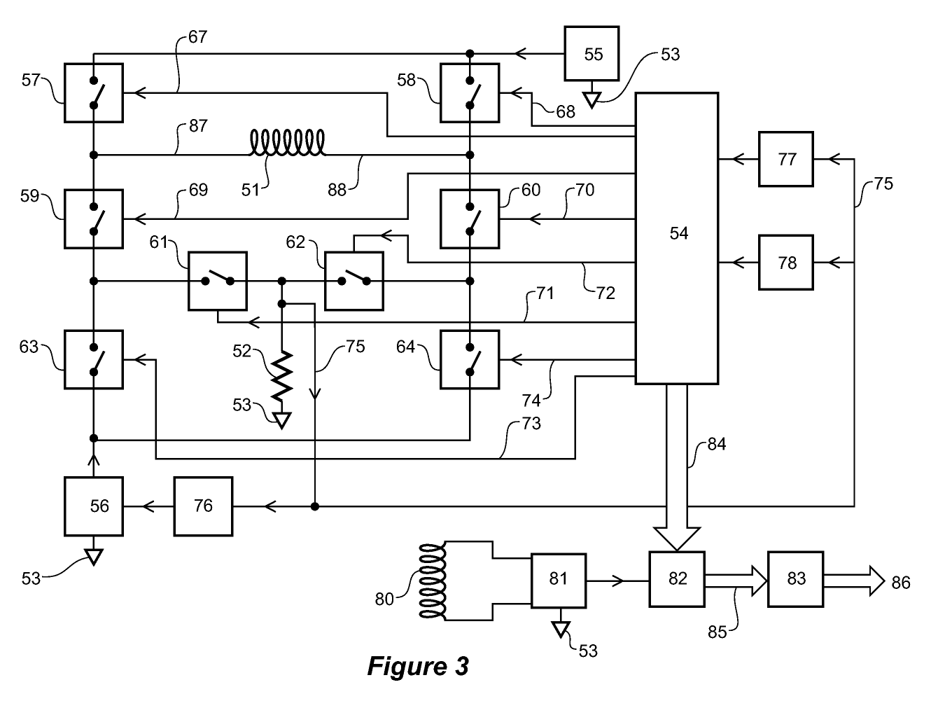

FIG. 3 shows an embodiment of the switching circuit of the transmit electronics 1 (FIG. 1) capable of producing the repeating transmit signal cycle of FIG. 2. In FIG. 3, transmit coil 51 is connected to transmit electronics consisting of elements 52, 53, 54, 55, 56, 57, 58, 59, 60, 61, 62, 63, 64, 67, 68, 69, 70, 71, 72, 73, 74, 75, 76, 77 and 78. A high voltage power source 55 is connected to one terminal of each of switches 57 and 58 (described herein as “high-side” switches). The other terminal of each of switches 57 and 58 is connected to transmit coil 51 and to switches 59 and 60 (described herein as “low-side” switches) respectively. The first high voltage power source 55 is connected to the system ground 53.

When closed, switch 61 connects switches 59 and 63 to the system ground 53 via a low-value resistor 52 (e.g. 0.05Ω). When closed, switch 62 connects switches 60 and 64 to the system ground 53 via the low-valued resistor 52. Switches 63 and 64 are connected to a low-voltage power source 56 which is also connected to the system ground 53 via the low-valued resistor 52.

All the switches are controlled to be “on” or “closed” (with very low resistance, e.g. 0.05Ω) or “off” or “open” (effectively open circuit) by timing control electronics 54. Switch 57 is controlled by control line 67, switch 58 via control line 68, switch 59 via control line 69, switch 60 via control line 70, switch 61 via control line 71, switch 62 via control line 72, switch 63 via control line 73, and switch 64 via control line 74.

A high voltage (e.g. +180V) from an output of the high-voltage power source 55 is fed to switches 57 and 58, and a low voltage, in this example a negative voltage (e.g. −1V) from an output of the low-voltage power source 56 is fed to switches 63 and 64. An average value of the high voltage from the high voltage power source is maintained to be constant by electronics within the high-voltage power source.

To produce a repeating transmit signal cycle with its respective current, as shown in FIG. 2 (b), the current 92 in the transmit coil 51 during the first high-voltage period 42 (FIG. 2 (c)) is increased rapidly in a positive sense. During this first high-voltage period 42 a first high voltage 44 (FIG. 2 (a)) is switched to the transmit coil 51. A first negative feedback loop ensures that the current 92 in the transmit coil 51 during the first high-voltage period 42 is such that when the switches switch the first low voltage 45 to the transmit coil 51 during the first low-voltage period 43, the current 93 in the transmit coil 51 in this first low-voltage period 43 remains constant because the initial current equals the applied first low voltage 45 divided by a total resistance which includes the resistance of the transmit coil and the equivalent output resistance of the transmit electronics (including switches, power supply, cables and tracks). After the first low-voltage period 43 with constant current 93, the current 96 in the transmit coil 51 during the second high-voltage period 47 increases rapidly in a negative sense. During this second high-voltage period 47, a second high-voltage 49 is switched to the transmit coil 51. A second negative feedback loop ensures that the current 96 in the transmit coil 51 during the second high-voltage period 47 is such that when the switches switch the second low voltage 50 to the transmit coil during the second low-voltage period 48, the current 97 in the transmit coil 51 during this second low-voltage period 48 remains constant because the current at the start of the second low-voltage period 48 equals the applied second low voltage 50 divided by the a total resistance which includes the resistance of the transmit coil and the equivalent output resistance of the transmit electronics (including switches, power supply, cables and tracks).

Any high-voltage period requires only at least a duration of switched high voltage and any low-voltage period requires only at least a duration of switched low voltage. For simplicity, the example illustrated in FIG. 2, described above, demonstrates only a particular embodiment where all high-voltage periods have switched high voltage for their entire durations and all low-voltage periods have switched low voltage for their entire durations.

The output resistance of the transmit electronics during the first low-voltage period 43 is typically slightly different to that of the second low-voltage period 48, owing to different switches and, hence, the voltage across the transmit coil (excluding switching electronics) is typically slightly different (the average voltage of the high power source being the same for both high-voltage periods), and thus the absolute value of the current in the transmit coil during the first low-voltage period and the second low-voltage period are likewise slightly different (not illustrated). The first negative feedback loop might control the duration of the first high-voltage period or the duration of the switched high voltage within the first high-voltage period, and/or the magnitude of the first high voltage 44, and the second negative feedback loop might control the duration of the second high-voltage period or the duration of the switched high voltage within the second high-voltage period, and/or the magnitude of second high voltage 49. It is usually simpler to arrange for the control of the durations.

The high-voltage source 55 can consist of a storage capacitor charged by both a switch-mode power supply and the energy in the transmit coil. The transmit coil also discharges the storage capacitor. During the high-voltage periods, the voltage across the capacitor may contain several percent ripple without causing significant deterioration in metal detector performance, so it is not necessary for the storage capacitor to be high in value. For example, suppose the high voltage is about 180V, the inductance of the transmit coil is about 0.25 mH and the current of the transmit coil at the commencement of the first high-voltage period is about −2 A (charging) and at termination about +2 A (discharging), and the storage capacitor with capacitance of about 0.47 g and, assuming that the switch mode power supply supplying the storage capacitor does not charge the storage capacitor significantly during the high-voltage periods, the voltage across the storage capacitor will change by about 6V as the energy from the transmit coil 51 is transferred to and from the storage capacitor during the high-voltage periods. Hence, the high-voltage power source 55, consisting of a switch mode power supply and the said storage capacitor, maintains a selected constant average value of the first high voltage (and second high voltage) which may include a few percent ripple throughout the repeating transmit signal cycle; thus the average first and second high voltages are controlled to be approximately constant.

Also as shown in FIG. 2, the average voltage switched to the transmit coil is of the same sign for the first high-voltage period 42 and the first low-voltage period 43, which is of the opposite sign to the average voltage switched for both the second high-voltage period 47 and second low-voltage period 48. The table below summarizes the switch combinations in FIG. 3 where S57=switch 57, S58=switch 58 etc. for the high-voltage power source 55 (e.g. +180V) being of opposite polarity to the low-voltage power source 56 (−1V).

| S57 | S58 | S59 | S60 | S61 | S62 | S63 | S64 | Voltage across transmit coil via switches |
|---|---|---|---|---|---|---|---|---|
| on | off | off | on | — | on | — | off | +first high voltage (nodes 87-88 = +180 V) |
| on | off | off | on | — | off | — | on | +first high voltage − first low voltage (e.g. |
| | | | | | | | | nodes 87-88 = +181 V) |
| off | on | on | off | on | — | off | — | −first high voltage (second high voltage |
| | | | | | | | | with e.g. nodes 87-88 = −180 V) |
| off | on | on | off | off | — | on | — | −first high voltage + first low voltage (e.g. |
| | | | | | | | | nodes 87-88 = −181 V) |
| off | off | on | on | on | on | off | off | Short circuit |
| off | off | on | on | on | off | off | on | −first low voltage (e.g. nodes 87-88 = +1 V) |
| off | off | on | on | off | on | on | off | +first low voltage (second low voltage with |
| | | | | | | | | e.g. nodes 87-88 = −1 V) |

For simplicity, the table immediately above assumes that the resistances in the transmit electronics and power sources are zero.

If the high-voltage power source (e.g. +180V) and the low-voltage power source (e.g. +1V) are of the same polarity, then the table is as follows:

| S57 | S58 | S59 | S60 | S61 | S62 | S63 | S64 | Voltage across transmit coil via switches |
|---|---|---|---|---|---|---|---|---|
| on | off | off | on | — | on | — | off | +first high voltage (nodes 87-88 = +180 V) |
| on | off | off | on | — | off | — | on | +first high voltage − first low voltage (e.g. |
| | | | | | | | | nodes 87-88 = +179 V) |
| off | on | on | off | on | — | off | — | −first high voltage (second high voltage with |
| | | | | | | | | e.g. nodes 87-88 = −180 V) |
| off | on | on | off | off | — | on | — | −first high voltage + first low voltage (e.g. |
| | | | | | | | | nodes 87-88 = −179 V) |
| off | off | on | on | on | on | off | off | Short circuit |
| off | off | on | on | on | off | off | on | −first low voltage (second low voltage with e.g. |
| | | | | | | | | nodes 87-88 = −1 V) |
| off | off | on | on | off | on | on | off | +first low voltage (e.g. nodes 87-88 = +1 V) |

The voltage across resistor 52 is proportional to the current in the transmit coil 51 for the low-voltage periods except when the transmit coil is short-circuited. This current manifests as a voltage at node 75 with respect to the system ground 53. This voltage at node 75 is monitored by an amplifier 77 in a first negative feedback loop (e.g. the current 93 of FIG. 2 (b) during the first low-voltage period 43 in FIG. 2 (c)) which controls in this embodiment a period set within the timing control electronics 54 (e.g. the first high-voltage period 42) within the repeating transmit signal cycle when the reactive transmit coil voltage is non-zero. Similarly, an amplifier 78 in a second negative feedback loop monitors the transmit coil current (e.g. the current 97 of FIG. 2 (b) during the second low-voltage period 48 in FIG. 2 (c)) as a voltage at node 75 and controls a different period set within the timing control electronics 54 within the repeating transmit signal cycle when the reactive transmit coil voltage is non-zero (e.g. the second high-voltage period 47).

A third negative feedback loop monitors the current of the transmit coil 51 for at least part of the first low-voltage period 43 and part of the second low-voltage period 48, and controls the average current in the transmit coil 51 to be constant during the first low-voltage period 43 and the second low-voltage period 48. This third negative feedback loop includes a slow response amplifier 76 which controls the voltage at the output of the low-voltage power source 56, e.g. the first low voltage 45 of FIG. 2 (a).

In short, the magnitude of the currents in low-voltage periods is maintained as constant by negative feedback loops within the transmit electronics to equal the current that flows when a low voltage is switched to the transmit coil via the switching electronics at the beginning of a low-voltage period. Hence the transmit coil reactive voltage is constant and equal to zero during low-voltage periods as v=Ldi/dt=0, where v is the transmit coil reactive voltage, i the transmit coil current and L the effective inductance of the transmit coil.

There is an advantage in maintaining the average current as constant. Assuming that only the combinations of the switches in the table are selected, the output impedances of the high-voltage power source 55 and the low-voltage power source 56 are low, the switches are of low “on” impedance, and the value of resistor 52 is low, then the driving impedance of the transmit electronics to transmit coil 51 is low throughout the whole repeating transmit signal cycle, or at least immediately after very short durations of switching transitions between the various voltages of the various power sources. For example, the durations of the said transitions may be of the order of 10 nanoseconds (10⁻⁸ s), whereas the duration of a repeating transmit signal cycle (refer to herein as a fundamental period) may be of the order of a millisecond (10⁻³ s). A “low” output impedance of the transmit electronics connected to the transmit coil may be considered to be, say, less than three times the equivalent series resistance of the transmit coil, at least during periods when the low voltage source 56 is switched to the transmit coil in either polarity sense. In particular, the driving impedance of the switching electronics and thus the output impedance of the transmit electronics presented to transmit coil 51 is low immediately after a short duration of switching transition between the high voltages to the low voltages. During these transitions, which are usually break-before-make for efficiency and reliability reasons, the impedance is still relatively low because the switches are either in the process of turning on or off, or present a capacitive low impedance given the very short duration switching times involved.

In order to maintain power efficiency, average voltage drops across the resistive components must be kept relatively low. As the high-voltage periods are considerably shorter than the low-voltage periods, the equivalent series resistance of the transmit electronics during the high-voltage periods (e.g. 2Ω) may be substantially higher than the equivalent series resistance of the transmit electronics during the low-voltage periods (e.g. 0.2Ω) whilst maintaining high power efficiency, assuming switch mode power supply 55 is efficient. Hence the “low impedance” of the transmit electronics throughout the repeating transmit signal cycle needs to be viewed in this context, and also in the context of having a relatively low value of storage capacitor in the high voltage source 55 as described above.

Receive coil 80 is connected to receive electronics 81, 82, 83, 84, 85, 86, which receives and processes a receive magnetic field to produce an indicator output at 86, the indicator output 86 at least indicating the presence of at least some metal targets affected by the transmit magnetic field. Receive coil 80 is connected to an input amplifier/filter 81, which in turn is connected to sampling circuits or synchronous demodulators 82, and the source of the synchronous demodulator control signals being provided via 84 by the timing control electronics 54. The receive electronics contains yet further signal processing 83 which processes outputs 85 of the synchronous demodulators 82, for example as described in some of the referenced patents which may be similarly usefully employed in this invention. The receive electronics processes, that is synchronously demodulates or samples, the received signal induced by receive magnetic field, during at least some of the receive periods, which is approximately free of any reactive X components as the transmit coil reactive voltage is approximately zero. At the time of writing, with switching analogue electronics, it is possible to maintain a reactive voltage of less than the order of 0.01% of the transmit coil applied voltage, for transmit currents of the order of Amperes. In particular, magnetic soils, which might include viscous superparamagnetic components, can be cancelled by similar methods to those disclosed in the patents incorporated by reference.

A first high and second high voltage assists with enhancing receive signals of fast time constant targets and may assist in improving signal-to-noise ratio if the techniques disclosed in U.S. Pat. No. 6,636,044 are employed. A useful absolute value of the first (and second) high voltage is within the range 10V to 400V. For a hand-held metal detector of limited battery power, a useful current in the transmit coil is of the order of Amperes, so that with a 1V low voltage source, the transmit power consumption is of the order of Watts. As the resistance of the transmit coil plus transmit electronics during the low-voltage period is of the order of, say, 0.1Ω to 1Ω, a useful absolute voltage of the first (and second) low voltage is within the range 0.1V to 15V.

The processing of the received signal by the receive electronics includes sampling and/or synchronous demodulation followed by averaging and/or low pass filtering to substantially remove signals with frequency of the repeating transmit signal cycle, to produce a receive reactive signal and a receive resistive signal, the receive reactive signal being responsive to non-dissipative components coupling between the transmit magnetic field and the receive magnetic field, and the receive resistive signal being responsive to dissipative components coupling between the transmit magnetic field and the receive magnetic field.

As the transmit coil conducts a finite current during the low-voltage periods of zero reactive voltage, the resulting receive signal is purely “resistive” (R) from energy-dissipative components and contains no reactive signal (X) components, but because the coupling between the transmit coil 51 and receive coil 80 varies as the coil is passed by reactive environmental components such as magnetic soils, a signal proportional to the time rate of change of coupling of the transmitted magnetic field to the receive coil is induced in the receive electronics and might manifest in the outputs of the synchronous demodulators 85 depending on the choice of synchronous demodulation. To cancel this signal, the receive electronics needs to measure a signal derived from a transmission period of non-zero transmit reactive voltage, e.g. the high-voltage periods. Thus a synchronous demodulator in 82 needs to measure the signal, during these non-zero transmit reactive voltage periods, to generate a receive reactive signal (X) responsive to the non-dissipative components that couple between the transmit magnetic field and receive magnetic field. This receive reactive signal is demodulated and then differentiated with respect to time to give a differentiated receive reactive signal and a first proportion of the differentiated receive reactive signal needs to be subtracted from a receive resistive signal (R) to give a modified receive resistive signal such that the said first proportion is selected to approximately cancel any components of the receive resistive signal proportional to the differentiated receive reactive signal. The modified receive resistive signal is further processed by the receive electronics in 83 to give an indicator output at 86.

In addition, the synchronous demodulators 82 need to be balanced to cancel the rate of change of static environmental magnetic fields such as the earth's field and magnetised rocks.

The advantage of maintaining an average constant current is that the resistances of the switching elements and of the transmit coil are functions of temperature, and either the selection of the first proportion is adjusted to compensate for changes of temperature if the voltage during the first and second low-voltage periods is fixed (with the first low voltage not necessarily equal to the second low voltage, and the first high voltage not necessarily equal to the second high voltage), or the value of the low voltages are set by the slow response third negative feedback amplifier 76 which maintains a constant average current in the transmit coil so that the transmit magnetic field is independent of temperature (except for very small changes in transmit coil dimensions).

Unlike the invention disclosed in WO 2008/006178 A1, this embodiment described herein does not propose to keep the transmit coil reactive voltage independent of the transmit coil inductance by adjusting the magnitude of the first low voltage throughout the whole repeating transmit signal cycle. Rather, the first voltage is held constant (or at least the mean absolute transmit coil current is, as disclosed below), and other parameters such as voltages and/or periods during non-zero transmit coil reactive voltages are adjusted to maintain constant current of fixed value during the first low-voltage period and other periods of constant current during the repeating transmit signal cycle. The effect of varying values of non-zero reactive voltages across the transmit coil is not ideal and is discussed below.

The table below outlines the differences between this invention and WO 2008/006178 A1.

| | This invention | WO 2008/006178 |
|---|---|---|
| Product of duration and | Modulated by soil magnetic | Constant |
| average absolute voltage of a | permeability | |
| non-zero reactive voltage | | |
| period (times of the order of | | |
| >0.1 s) | | |
| Product of duration and | Independent if average absolute | Independent |
| average absolute voltage of a | transmit current constant, but | |
| non-zero reactive voltage | dependent if applied voltage to | |
| period as a function of | transmit coil during zero reactive | |
| temperature | transmit voltage periods is constant | |
| | and temperature independent | |
| Average absolute transmit | Constant | Modulated by soil |
| current ignoring temperature | | magnetic permeability |
| effects | | |
| Average absolute transmit | Dependent if applied voltage to | Independent |
| current as a function of | transmit coil during zero reactive | |
| temperature | transmit voltage periods is | |
| | temperature independent, else | |
| | independent if average absolute | |
| | transmit current constant | |
| Applied voltage to transmit | Constant | Modulated by |
| coil during zero reactive | | magnetic soils |
| transmit voltage periods | | |
| ignoring temperature effects | | |
| (times of the order of >0.1 s) | | |
| Applied voltage to transmit | Effectively constant (but strictly | Constant if sample- |
| coil during zero reactive | speaking may change by an | and-hold electronics |
| transmit voltage periods | extremely small amount as a | employed to ensure |
| during a specific period (of | function of temperature) | this. |
| the order of transmit | | |
| fundamental period, e.g. ms) | | |
| Applied voltage to transmit | Dependent if average absolute | Dependent |
| coil during zero reactive | transmit current constant, but | |
| transmit voltage periods as a | independent if applied voltage to | |
| function of temperature | transmit coil during zero reactive | |
| (times of the order of >0.1 s) | transmit voltage periods is constant. | |

In this table, the references to “times of the order of >0.1 s” assumes that soil magnetic permeability may change significantly over periods of this order as the transmit coil traverses such soils, but does not change significantly during periods substantially shorter than 0.1 s.

To compare this embodiment of the present invention to a conventional pulse induction detector, assume:
a. In both detectors, only transmit coil losses are taken into account. These losses are normalised to be the same in both cases, with ideal lossless electronics and with the time constant of the transmit coil plus transmit electronics effectively infinite, for simplicity. However, for the purposes of calculating the power consumption of the transmit electronics, assume a very small transmit coil effective series resistance. The synchronous demodulator outputs are normalised to wideband input white noise, and the electronic bandwidths are assumed to be the same in both detectors.
b. The repeating transmit signal cycle of a pulse induction system includes a low-voltage period followed by a back-emf high-voltage period which is, in turn, followed by a zero transmit current period. In the case of a pulse induction system, a voltage of −1 voltage units is applied to the transmit coil for the low-voltage period of 1 time unit, and the duration of the back-emf high-voltage period is effectively zero. The receive electronics synchronously demodulates with a gain of +1 during the following zero transmit current period of ½ a time unit then, following this, the receive electronics synchronous demodulates with a gain of −1 for a further zero transmit current period of ½ a time unit. Hence, the repeating transmit signal cycle of a pulse induction system has a duration of 2 time units.
c. In this embodiment of the invention, the repeating transmit signal cycle shown in FIG. 2 has a duration of 2 time units. The receive electronics synchronously demodulates with a gain of +1 for the first low-voltage period and a gain of −1 for second low-voltage period.

If there is a first order metal target of time constant τ=L/r (where L is the effective first order inductance, and r is the effective resistance), where τ>>1, the ratio of the demodulated signal produced by the receive electronics of an embodiment as described above and the pulse induction system as disclosed in the embodiment above, the ratio of the demodulated signal asymptotically approaches

$$8 \sqrt{\frac{2}{3}} τ \qquad ( 2 )$$

Hence, for long time constant targets, the demodulated signal from the described embodiment of this invention is substantially larger than that for an “equivalent” pulse induction system as discussed in general terms above.

The first and second high-voltage periods of the embodiment are modulated slightly when the inductance of the transmit coil is modulated by the magnetic susceptibility of magnetically mineralised soils as the transmit coil is moved over such soils. This affects the receive signal slightly, in particular the response from viscous superparamagnetic soil components which need to be accurately cancelled as disclosed in the patents incorporated by reference.

The receive signal from viscous superparamagnetic soil components for an approximate current square-wave during the first low-voltage period is proportional to

$${\sum }_{i = 0}^{∞} {( - 1 )}^{i} ( \frac{ln \{ \frac{t + iT + {P}_{hv}}{t + iT} \}}{{P}_{hv}} ) \qquad ( 3 )$$

where T is the duration of the low-voltage periods, Pₕᵥ is the duration of high-voltage periods and Pₕᵥ<<T. If the inductance of the transmit coil increases by x % while passing the coil over magnetically permeable soils (typically <1% in most highly magnetically permeable gold field soils), then Pₕᵥ increases, likewise, by x %. Only the first term in (3) is significantly affected, namely

$$\frac{ln \{ \frac{t + {P}_{hv}}{t} \}}{{P}_{hv}} \qquad ( 4 )$$

In terms of cancellation of viscous superparamagnetic soil components, the shape of the decay changes by ln [t+(1+x)Pₕᵥ] rather than ln [t+Pₕᵥ], assuming the high voltages are held constant (for example periods 42 and 47 in FIG. 2).

As sampling or synchronous demodulation commences at several times of Pₕᵥ, e.g. say 2 times minimum, ln [t+(1+x)Pₕᵥ] commences at a minimum of ln [2Pₕᵥ+(1+x)Pₕᵥ] or ln [3Pₕᵥ+xPₕᵥ].

As the maximum of x is about 1%, then [3Pₕᵥ+xPₕᵥ] is, at maximum, approximately 0.3% more than 3Pₕᵥ. Assuming that the receive signal is an accumulation (by integration or averaging) of signals with t>>3Pₕᵥ, this error is very small and indeed does not adversely affect performance in practice.

Alternatively, negative feedback loops may control output voltages of power source/s.

Several different voltages from additional power sources of various voltages may be switched to the transmit coil for various durations within each of the first and second low-voltage periods, and first and second high-voltage periods, which may include zero volts, for example. Some of the associated periods may be associated with zero transmit coil reactive voltage, and others with non-zero reactive voltage. To take advantage of pulse induction theory, the average voltage applied across the transmit coil during a high-voltage period should be about at least three times greater (e.g. 20 times in the case of pulse induction) in magnitude than the average voltage applied across the transmit coil during a low-voltage period. Each different period of zero reactive transmit coil voltage within the repeating transmit signal cycle requires an associated negative feedback loop to obtain high accuracy in maintaining constant current to avoid any X contamination in the Rx signal.

Whilst the waveform in FIG. 2 shows just two different low voltages and two different high voltages switched to the transmit coil, the power sources may provide other voltage outputs, and further switches controlled by timing electronics 54 may switch these to the transmit coil.

Regardless of the different voltages switched to the transmit coil, the average voltage value across the transmit coil in the first high-voltage period is opposite in polarity to the average voltage value across the transmit coil in the second high-voltage period, and the average voltage value in the first low-voltage period across the transmit coil is opposite a polarity to the average voltage value across the transmit coil in the second low-voltage period.

As the transmit coil is low-impedance driven, there is no damped back-emf transmit coil decay signal as there is in pulse-induction metal detectors. This decaying signal places a limit on the capability of detecting fast time-constant targets, such as small gold nuggets, without the problems of reactive signal (X) contamination. In this embodiment, due to the absence of a damped transmit decay signal, receive demodulation may occur with less delay following high-voltage periods, improving the capability of detecting targets of fast time constant.

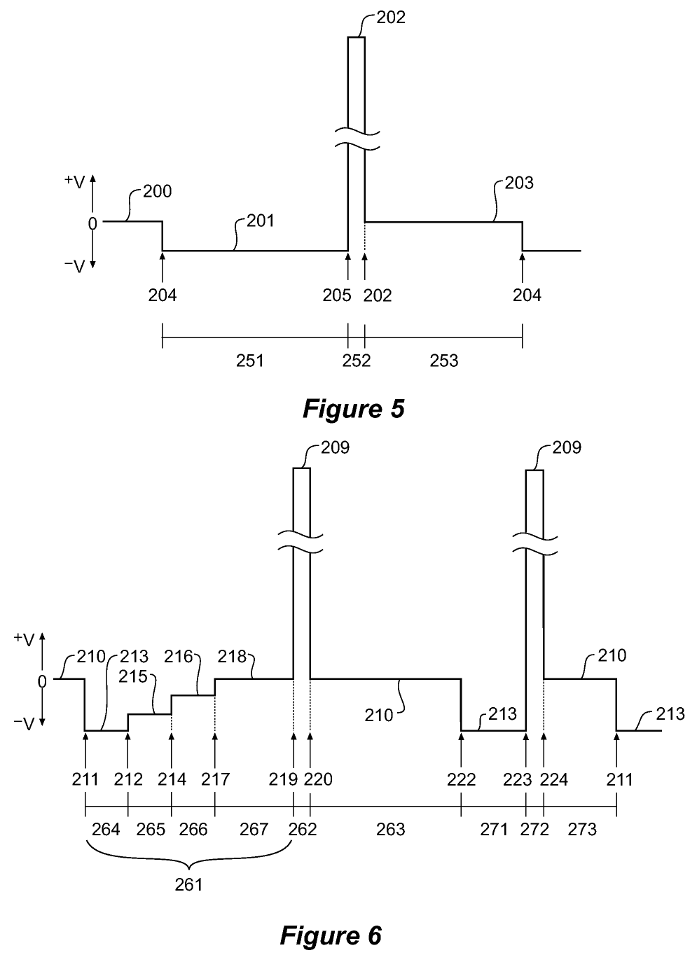

In another embodiment of the repeating transmit signal cycle, the repeating transmit signal cycle includes a low-voltage period (“an energising period”), the low-voltage period being followed by a high-voltage period (“a back-emf period”), and the high-voltage period followed by a zero-voltage period; the zero-voltage period is the said receive period, and the average value of the transmit coil current during the zero-voltage period of every repeating transmit signal cycle is zero. An example voltage waveform of this embodiment is shown in FIG. 5.

Although this embodiment of the repeating transmit signal cycle is that of a PI detector, the waveform of the applied voltage and operation is significantly different from conventional arts for the reason explained below.

In a simple form, the transient output from a conventional pulse induction receive coil, in the ideal case of zero capacitive coupling but finite mutual inductance between the transmit and receive coils, is of the form (1) as discussed before.

The transient output from the receive coil of the present invention, in the ideal case of zero capacitive coupling but finite mutual inductance between the transmit and receive coils, is of the form

ae^{-t/τ} (5)

This is because, in this embodiment of the present invention, the transmit coil is driven at low impedance throughout the repeating transmit signal cycle without any damped decays immediately after the transition between the high-voltage period and the zero-voltage period. Given that the critically damped time constant of the transmit coil, including associated transmit circuitry, is usually significantly longer (e.g. 50%) than that of the receive coil, (5) has an even faster decay than the ratio of (1) and (5) would imply.

Increased power efficiency and reduced delay time between the back-emf and receive sampling or synchronous demodulation is possible by driving the transmit coil with a low impedance during the whole transmit cycle, in a manner similar to that disclosed in US 2008/0048661, incorporated by reference, but with control to ensure minimal transmit current during the receive period, and also without high attenuation of slow time constant target signals during the zero transmit current periods which is the case in US 2008/0048661.

By way of comparison, suppose a system conforming to the teaching of US 2008/0048661 consists of a positive high-voltage period of duration A and of voltage V, followed by a transmit low-voltage period of duration T with −2 U volts applied to the transmit coil, then followed by a “back-emf” high-voltage period of duration A and of voltage V, such that for ideal electronics (no power dissipation etc), VA=UT. For simplicity of understanding, let T=VA=1. At the end of the “back-emf” high-voltage period, the transmit current is zero and zero volts is applied across the transmit coil for the zero-voltage period of duration T, whereafter the cycle repeats.

During this zero-voltage period, the signal from a first-order metal target of time constant τ=l/r where l is the effective first order inductance, and r the effective resistance, is proportional to

Ue^{-t/τ}/τ[1+e^{-1/τ}−2τ(1−e^{-1/τ)]/(}1−e^{-2/τ}) (6)

assuming A<<T and of negligible duration.

An “equivalent” pulse induction system with ideal electronics, would have, for example, a repeating transmit signal cycle consisting of an low-voltage period of duration T (with −U applied to the transmit coil so that the power dissipated in the coil is the same as the above for a real situation for a fair comparison), a “back-emf” high-voltage period of voltage V for a period A, such that VA=UT and T=VA=1, and a zero-voltage period of duration T following the “back-emf” high-voltage period, whereafter the cycle repeats. If the “back-emf” period is very short and the transmit coil current is zero during the zero-voltage period, and the signal from a first order metal target during the zero-voltage period is proportional to

Ue^{-t/τ}/τ[1−τ(1−e^{-1/τ})]/(1−e^{-2/τ}). (7)

If τ>>T, that is τ>>1, then the signal from (7) is 3τ times larger than that from (6) during the zero-voltage period.

Hence, for long time constant targets, the signal for the pulse induction system, and that includes the arrangement disclosed in this specification, is larger than that disclosed in US 2008/0048661.

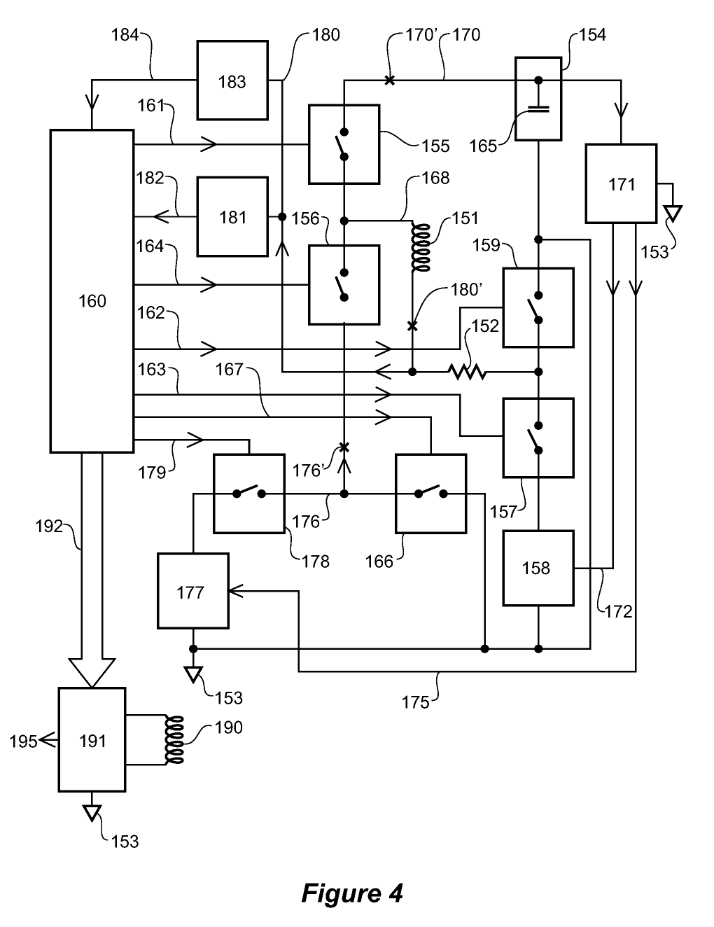

FIG. 4 shows an embodiment of the switching circuit of the transmit electronics capable of producing repeating transmit signal cycle of FIG. 5, which are pulse induction-like waveforms from the low impedance repeating transmit signal cycle source. The transmit electronics consists of all the elements except 151, 190, 191, 192 and 195. The transmit electronics transmits a repeating transmit signal cycle across a transmit coil 151 in series with resistor 152. The resulting current in the transmit coil 151, which produces an alternating magnetic field, may be measured at 180 as a voltage across resistor 152.

Switching electronics consisting of a plurality of switches within the transmit electronics is connected across the series transmit coil 151 and resistor 152 to connect various power sources 154, 158, and 177 to the transmit coil 151 or to short circuit the transmit coil.

Switch 155 and 159 can switch the transmit coil 151 to a first power source 154 which produces a first voltage (e.g. +180V) at its output 170 relative to the system ground 153. A useful absolute value of the first voltage is within the range 10V to 400V.

Switch 166 can switch the transmit coil 151 via switch 156 and 159 to the system ground 153. Switch 178 can switch the transmit coil 151 via switch 156 and 159 to a second power sources 177. A useful absolute voltage of the second voltage is within the range 0.1V to 15V, e.g. −15V.

The transmit coil 151 is connected to switches 159 and 157 via series resistor 152. Switch 159 connects resistor 152 (and thus transmit coil 151) to the system ground 153 when “on”, and switch 157 connects resistor 152 (and thus transmit coil 151) to a third power source 158 when “on.” The third power source 158 produces at least effectively one different voltage other than zero voltage, the first voltage or second voltage (e.g. +5V). A useful absolute voltage of the third voltage is within the range 0.1V to 15V.

Switches 155, 156, 157, 159, 166 and 178 are controlled to be either “on” (e.g. 0.1Ω) or “off” by timing electronics 160. For example, switch 155 via control line 161, switch 156 via control line 164, switch 159 via control line 162, switch 157 via control line 163, switch 166 via control line 167, and switch 178 via control line 179.

The below summarizes the switch combinations where S151=switch 151, S152=switch 152 etc.

| | | | | | | Voltage across transmit coil |
|---|---|---|---|---|---|---|
| S155 | S156 | S157 | S159 | S166 | S178 | 151 and resistor 152 |
| on | off | on | off | — | — | first-third |
| on | off | off | on | — | — | first |
| off | on | on | off | on | off | -third |
| off | on | on | off | off | on | second-third |
| off | on | off | on | on | off | short |
| off | on | off | on | off | on | second |

The table assumes that both the first power source and second power source are of opposite polarity to the third power source. If this is the case with the first voltage being say 180V, the third voltage being say +5V, and the second voltage say −10V, then the low voltages that may be applied to the transmit coil where a “positive” polarity sense is with switch 155 and 156 end 168 of the transmit coil 151 being positive relative to the resistor 152 end of the transmit coil 151, are 0V (S156=on, S159=on, S166=on, others off), −5V (S156=on, S157=on, S166=on, others off), −10V (S156=on, S178=on, S159=on, others off), −15V (S156=on, S157=on, S178=on, others off). To avoid short-circuiting power sources, either switch 155 is closed (“on”) or switch 156 closed, and either switch 166 is closed or switch 178 closed, and either switch 159 is closed or switch 157 is closed. If the third voltage is say −5V, and the second voltage −10V, then the low voltages that may be applied to the transmit coil are +5V, 0V, −5V, and −10V and so on.

Assuming that only the combinations of the switches in the table are selected, and the output impedances of the first power source 154, the second power source 158, and the third power source 177 are low, and the switches have low “on” impedance when closed, and the value of resistor 152 is low (e.g. 0.05Ω), then the driving impedance of the transmit electronics to transmit coil 151 is low throughout the whole repeating transmit signal cycle or sets of repeating sequences within a repeating transmit signal cycle provided to the transmit coil or at least immediately after very short duration switching transitions between the various voltages of the various power sources. For example, the duration the said transitions may be of the order of 10 ns, whereas the repeating transmit signal cycle fundamental period may be of the order of ms. A “low” output impedance of the transmit electronics connected to the transmit coil may be considered to be, say, less than three times the equivalent series resistance of the transmit coil, at least during the zero transmit period. In particular, the driving impedance of the switching electronics, and thus the transmit electronics to transmit coil 151, is low immediately after a short duration switching transition between the first voltage to zero voltage. During these transitions, which are usually break-before-make for efficiency and reliability reasons, the impedance is still relatively low because the switches are either in the process of turning on or off, or present a capacitive low impedance given the switching times involved. However, even though this said capacitive impedance may not be as low as the “on” resistance of the switches plus output impedance of the power sources, the times involved are so relatively short that effectively it could be said that the output impedance is low even including the transitions.

Receive coil 190 is connected to receive electronics 191, adapted and arranged to receive and process a received magnetic field to produce an indicator output at 195, the indicator output at least indicating the presence of at least some metal targets under the influence of the alternating transmitted magnetic field. Transmit coil 151 and receive coil 190 may be the same coil. The receive electronics contains signal processing, usually including sampling or synchronous demodulation, for example as described in some of the patents incorporated by reference, and the source of synchronous demodulation signals being provided via 192 from the timing electronics 160.

A second negative feedback loop is set up around the path including the voltage at 180 across resistor 152 being fed to an input of an amplifier 181 which includes components to set the stability of negative feedback, an output 182 of the amplifier 181 controlling the duration of a period of a switch set within the timing electronics 160, such as, for example the duration of an low-voltage period commencing at time 204 and terminating at time 205, as depicted in FIG. 5, for which switch 178 connects the transmit coil 151 to the second power source 177. The control of this period within a transmit low-voltage period, high-voltage period, zero-voltage period sequence affects the transmit coil current throughout the said sequence, but this effect ceases during a zero-voltage period if zero volts is applied across the transmit coil and transmit coil current is zero. Sampling the transmit coil current during a zero-voltage period, when switch 156, switch 159 and switch 166 are closed to short circuit the transmit coil 151 (in series with resistor 152) will cause the second negative feedback loop to maintain a value of the transmit coil current during the said sampling period, such as zero current, assuming that the voltage of the first power source 154, and the second power source 177 and the duration of the high-voltage period are of fixed value. In FIG. 4 when switch 159 is closed, the voltage at the node 180 of coil 151 and resistor 152 relative to the system ground 153 equals the current flowing through total resistance of resistor 152 plus switch 159 (plus circuit board tracks), assuming that the negative feedback loop input impedance is relatively very high.

In FIG. 4, the said first power source 154 is shown as a first capacitor 165. Switch-mode power supply 171 converts energy from the first power source 154 to supply the second power source 177 via line 175, but this can also supply the third power source 158 via line 172.

Another negative feedback loop, a first negative feedback control electronics contained within switch-mode power supply 171, is responsive to the first voltage at 170 and controls the amount of energy converted from the first power source 154 back to second power source 158 (and/or the third power sources 177) so as to maintain the first voltage to be approximately a selected average constant value.

It is not necessary for the first capacitor 165 to be high in value so that, during the high-voltage period, the voltage across the first capacitor 165 is effectively constant as current flows into the capacitor. This voltage may change by several percent without causing significant deterioration in performance. For example, suppose the first voltage at 170 is about 180V, the transmit coil 151 inductance say 0.25 mH and the transmit coil current at the commencement of the high-voltage period is say 3 A, and the first capacitor 165 say 1 μF, and assuming that the switch mode power supply 171 does not discharge the first capacitor 165 significantly during of the high-voltage period, then the voltage across the first capacitor will increase by about 6V as the energy from the transmit coil 151 is transferred to the first capacitor 165 during the high-voltage period. Hence, the switch mode power supply 171 maintains the first voltage to be approximately a selected constant average value which may include several percent ripple throughout the repeating transmit signal cycle.

A high first voltage assists with enhanced receive signals of fast time constant targets, and may improve signal-to-noise ratio if the techniques disclosed in U.S. Pat. No. 6,636,044 are employed.

In order to maintain power efficiency, average voltage drops across the resistive components can be kept low relative to the average transmit coil reactive voltage during the low-voltage period and high-voltage period. As the transmit coil reactive voltage is typically considerably higher during the high-voltage period (e.g. 180V) than the low-voltage period (e.g. 10V), this means that the equivalent series resistance of the transmit electronics during the high-voltage period (e.g. 2Ω) may be substantially higher than the equivalent series resistance of the transmit electronics during the low-voltage period (e.g. 0.25Ω) whilst maintaining high power efficiency, assuming switch mode power supply 171 is efficient. Hence the “low impedance” of the transmit electronics throughout the repeating transmit signal cycle needs to be viewed in this context.

Waveform FIG. 5 depicts a zero-voltage period 253 when the transmit coil 151 (in series with resistor 152) is shorted, and shown as being zero volts 203. At the end of that period a negative voltage 201 (e.g. −5V) from the second power source is applied across the transmit coil during a low-voltage period (period 251) commencing at time 204 and terminating at time 205, and the transmit coil current increases “negatively.” At time 205, the transmit coil is switched to a first power source 154 for a short duration high-voltage period (period 252). During this high-voltage period, commencing at time 205 and terminating at time 202, the transmit current is rapidly reduced in magnitude because the first voltage at 170 is high and positive. Following this short high-voltage period, the repeating transmit signal cycle, commencing at time 202 is repeated, commencing with another zero-voltage period 253 again.

Changes in any voltage or any period (except the zero-voltage period if the transmit current is zero) will cause a change in transmit current throughout the cycle, so the negative feedback loop may change any of these variables to set transmit current to zero during the zero-voltage period. It is easiest to change a period, such as the low-voltage or high-voltage period, rather than a voltage but this alternative is not excluded from this disclosure.

A negative feedback loop may measure the transmit current during the zero-voltage period 253 and control the switching time 204, that is the duration of the low-voltage period 251, or switching time 205, that is the duration of the high-voltage period 252 and low-voltage period 251, so as to maintain zero transmit current during the zero-voltage period 253.

Switch 156 and switch 155 can withstand the voltage of the first power source 154, (e.g. say 200V devices), whereas switches 157, 159, 166 and 178 can withstand the voltages of the second 177 and third power source 158 (e.g. say 30V devices).

To illustrate the current in the system:

Suppose all elements are ideal (e.g. the transmit coil is a pure superconductor inductor of inductance L with zero series resistance, the power sources have zero output impedance, switches are either zero ohm (on) or infinite (off) etc.). The high-voltage period of duration P1 of first voltage V1 is followed by a zero-voltage period of which is followed by low-voltage period of duration P2 and second voltage V2, then the cycle repeats with a high-voltage period again.

If the transmit coil current during zero-voltage period is zero, then it is zero when low-voltage period commences. At the end of the low-voltage period and thus beginning of the high-voltage period, the transmit coil current is P2V2/L. At the end of the high-voltage period, the transmit coil current is P2V2/L−P1V1/L. Hence the transmit coil current is zero during the zero-voltage period if P1V1=P2V2, and thus each of P1, P2, V1 and V2 will affect the transmit coil current during the zero-voltage period. Thus, a negative feedback loop monitoring the transmit coil current during the zero-voltage period can feedback a signal to control either P1, P2, V1 or V2, or a combination of them, to maintain the transmit coil current at zero during the zero-voltage period.

The receive electronics 191 receives and processes a magnetic field, during at least some of the zero-voltage period 253, to produce an indicator signal indicating the presence of a metal within the magnetic field generated by the transmit coil, the indicator signal being free of reactive signal X because of the zero transmit reactive signal, and because of sufficient delay following the transition between the high-voltage period and zero-voltage period for the value of (5) to become insignificant.

FIG. 6 shows another embodiment of the repeating transmit signal cycle. It depicts a multi-period multi-voltage waveform which includes two versions of the type of waveform described in relation to the waveform depicted in FIG. 5. The first such version is depicted as low-voltage period 271, high-voltage period 272 and zero-voltage period 273, they corresponding closely to the low-voltage period 251, high-voltage period 252 and zero-voltage period 253 of FIG. 5.

The second version is depicted as low-voltage period 261, high-voltage period 262 and zero-voltage period 263. Although it is not as obvious, the principles are the same and the additional waveform voltages during low-voltage period 261, namely periods 264, 265, 266 and 267, can have advantageous effects, namely increasing the current initially relatively rapidly, then maintaining the transmit coil current at a more or less constant value. This assists with the detection of long time-constant targets whilst maintaining a relatively short fundamental period.

To generate such a waveform as depicted in FIG. 6, the transmit coil is short circuited at time 220 for a zero-voltage period 263, which commences at time 220 and terminates at time 222. At time 222, a negative voltage 213 (e.g. −15V), being a third voltage (say +5V) from the third power source 158 subtracted from a second voltage (say −10V) from second power source 177, is applied across the transmit coil during an low-voltage period 271 commencing at time 222 and terminating at time 223. During this low-voltage period 271, switches 156, 178 and 157 are “on” and all other switches “off”, and transmit current increases “negatively” and moderately rapidly. At time 223, the transmit coil is switched to the first power source 154 of first voltage 209 for a short duration, a high-voltage period 272, commencing at time 223 and terminating at time 224. As this voltage is high and positive, the transmit current rapidly decreases in magnitude. Following this high-voltage period 272 is a zero-voltage period 273, during which the transmit coil 151 (in series with resistor 152) is short-circuited with switches 156, 159 and 166 “on” and all other switches “off.” At time 211, a low-voltage period 261 of periods 264, 265, 266 and 267 commences. At time 211, a negative voltage 213 (e.g. −15V) is again switched across the transmit coil for a period 264 commencing at time 211 and terminating at time 212, and the transmit current increases “negatively” and moderately rapidly.

At time 212, the transmit coil is switched just to the second power source 177, to a lower negative voltage 215 (−10V) than that applied during the period 264, for a period 265 commencing at time 212 and terminating at time 214. As the applied voltage is lower, the transmit current increases more gradually “negatively.” At time 214, the transmit coil is switched just to the third power source 158 to a lower negative voltage 216 (−5V) than that applied during the period 264 or period 265, for a period 266 commencing at time 214 and terminating at time 217. As the applied voltage is lower still, the transmit coil current increases even more gradually “negatively.” At time 217, the transmit coil 151 (in series with resistor 152) is shorted during a period 267 commencing at time 217 and terminating at time 219 and shown as zero volts 218.

During this period 267 switches 156, 159 and switch 166 are “on” and all other switches are “off” and the transmit current decays according to the transmit coil circuit time constant which includes the switching electronics output impedance (e.g. a total series effective resistance of say 0.5Ω for say L=0.25 mH transmit coil; that is a 0.5 ms time constant). Hence the reactive voltage across the transmit coil (−Ldi/dt) is non-zero but small.

This time constant varies slightly during the whole cycle as the switching electronics presents different output impedances owing to different switches and power source impedances.

At time 219, the transmit coil is switched to the first power source 154 of a first voltage 209 for another short duration, a high-voltage period 262 commencing at time 219 and terminating at time 220. As the first voltage is high and positive, so the transmit current rapidly decreases in magnitude. During this period 262, switches 155 and 159 are closed (i.e. “on”) and switch 156 open (i.e. “off”). Following this short high-voltage period, the cycle repeats to form a repeating transmit signal cycle.

A fundamental period of the repeating transmit signal cycle in this embodiment may include both identical and different sequences of low-voltage period, immediately followed by a high-voltage period, immediately followed by a zero-voltage period. At least one different negative feedback control electronics is to provide for each different sequence of low-voltage period, immediately followed by a high-voltage period, in turn immediately followed by a zero-voltage period within the fundamental repeating transmit signal cycle, during which the receive electronics receives and processes a magnetic field within the zero-voltage period, to maintain zero transmit coil current during the zero-voltage periods, in addition to the negative feedback loop within the switch-mode power supply 171.

Each different negative feedback control electronics senses the transmit coil current during a zero-voltage period, and provides a control signal to control the duration or magnitude of one or more switched voltages within the immediately preceding low-voltage period and/or high-voltage period, such that the transmit coil current during the zero-voltage period is maintained to be substantially zero.

Hence, for a transmit waveform of FIG. 6, a second negative feedback loop, including an amplifier 181 which includes components to set the stability of negative feedback, can measure the transmit current during the zero-voltage period 273, and an output 182 of the amplifier 181 can control the timing of, say, time 222 (low-voltage period 271) or time 223 (low-voltage period 271 and high-voltage period 272), so as to maintain the current during the zero-voltage period 273, to be zero.

The current during the zero-voltage period 263 can be controlled by another negative feedback loop, a third negative feedback control electronics including amplifier 183, which includes components to set the stability of negative feedback, which measures the transmit coil current during the zero-voltage period 263, and an output 184 of the amplifier 183 can control the timing of, say, time 211 (period 264), or 212 (period 264 and period 265), or 214 (period 265 and period 266), or time 217 (period 266 and the period 267), or time 219 (period 267 and the high-voltage period 262), so as to maintain the current, during the zero-voltage period 263, to be zero.

These times will be modulated slightly as the inductance of the transmit coil is modulated by the magnetic susceptibility of magnetically mineralised soils as the transmit coil is moved over such soils. Alternatively, a negative feedback loop may control output voltages of power source/s.

Thus, the receive electronics can sample or synchronously demodulate, with sufficient delay following the transition between the high-voltage period and zero-voltage period for the value of (5) to become insignificant, during the zero-voltage periods 273 and 263 so as to produce receive demodulated signal without X contamination.

Advantage is gained by selecting the first voltage to be at least three times greater (say 20 times but can be as low as 3 times with reasonable advantage) in magnitude than either that of the second or any voltage from the third power source or combination, in accordance with the well-known pulse induction theory. Whilst the waveform in FIG. 6 shows just three different negative voltages applied to the transmit coil, the power sources may provide other voltage outputs, and further switches controlled by timing electronics 160 may switch these to the transmit coil.

In another embodiment, the repeating transmit signal cycle may take the form of that produced by the pulse induction system disclosed in U.S. Pat. No. 6,653,838 where the transmit sequence consists of the transmit coil being switched to a second power source of a negative low second voltage (e.g. −5V) for an low-voltage period of roughly a quarter or so of the fundamental period when the transmit coil current increases from zero to a negative peak. This period is then followed by a very short duration high-voltage back-emf period where all the magnetic energy stored in the transmit coil is transferred to a first power source, e.g. a first capacitor, as a charge. The first capacitor may operationally be at a first voltage of say 180V.

Next follows a zero-voltage period when the switching electronics shorts out the transmit coil, and the receiver receives receive signals, for say slightly more than a quarter of the fundamental period. Thereafter, the transmit coil is switched to the first power source for a very short duration low-voltage period so that the resulting discharge of the first power source equals the charge during the charging back-emf (high-voltage) period.

Thereafter, the resulting energy of the magnetic field stored by the transmit coil is transferred to the second power source as a charge for a little less than a quarter of the fundamental period as a high-voltage period. Once the magnetic field becomes zero, the transmit coil is shorted out by the switching electronics for another zero-voltage period for about a quarter of the fundamental period, when the receiver receives receive signals again. Three negative feedback loops are to provide for setting the voltage across the first capacitor, and zero transmit coil current during both the receive periods when the transmit coil is shorted. These three negative feedback loops may control three of the following variables:
the durations of the two periods when the transmit coil is switched to the first power source; and
the durations of the two periods when the transmit coil is switched to the second power source.

The system described in this embodiment does not depend on a switch-mode power supply to convert energy from the first power source back to the second power source as this action is intrinsic to the waveform because the transmit coil acts as a switching inductor for the switch-mode power supply, although using an additional power supply for the first power source might allow better definition of the “back-emf” (high-voltage) period when the transmit coil is switched to the second power source following a period of the transmit coil switched to the first power source. Alternatively, the first power source may provide the input power, and the second power source may be a passive storage capacitor. This system is referred to herein as a “fully symmetric bipolar system.”

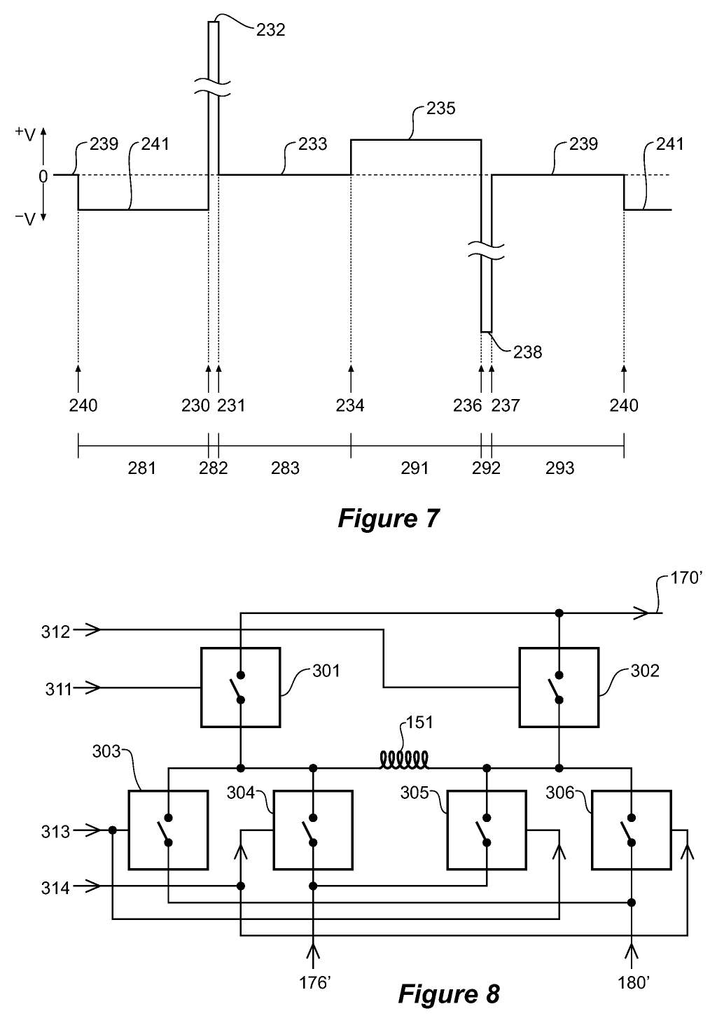

FIG. 7 shows an embodiment of the “bipolar” repeating transmit signal cycle, where the repeating transmit signal cycle includes at least two different sequences, the first sequence including a first low-voltage period, a first high-voltage period and a first zero-voltage period, and the second sequence including a second low-voltage period, a second high-voltage period and a second zero-voltage period. The first and second zero-voltage periods are the first and second receive periods respectively, and at least one of the first low-voltage period, the first high-voltage period and the first zero-voltage period, differs from the respective second low-voltage period, second high-voltage period and second zero-voltage period in at least voltage and/or duration.

Referring to FIG. 7, the high-voltage period 282 commences at time 230 and terminates at time 231 during which the voltage switched to the transmit coil is the first voltage 232. An output impedance of the transmit electronics to the transmit coil is low at least immediately after the transition 231 of the first voltage 232 to zero voltage 233 in response to the switches selecting the first voltage 232 switched to the transmit coil followed by the switches selecting zero volts 233 switched to the transmit coil. The zero-voltage period 283 commences at time 231 and terminates at time 234 during which the voltage switched to the transmit coil is zero volts 233, and during this period the current through the transmit coil is substantially zero. An low-voltage period 291 commences at time 234 and terminates at time 236 during which the voltage switched to the transmit coil is a fifth voltage 235, and during this period the current through the transmit coil increases “positively” with an associated transmit coil circuit time constant. A high-voltage period 292 commences at time 236 and terminates at time 237 during which the voltage switched to the transmit coil is a fourth voltage 238, and during this period, the transmit coil current rapidly decreases to zero owing to the large negative fourth voltage 238. An output impedance of the transmit electronics to the transmit coil is low, at least immediately after the transition 237 of the fourth voltage 238 to zero voltage 239, in response to the switches selecting the fourth voltage 238 switched to the transmit coil followed by the switches selecting zero volts 239 switched to the transmit coil. A zero-voltage period 293 commences at time 237 and terminates at time 240 during which the voltage switched to the transmit coil is zero volts 239, and during this period the current through the transmit coil is substantially zero. A low-voltage period 281 commences at time 240 and terminates at time 230 during which the voltage switched to the transmit coil is the second voltage 241, and during this period the current through the transmit coil increases “negatively” with an associated transmit coil circuit time constant. During the high-voltage period 282 which follows, the transmit coil current rapidly decreases to zero.

Receive electronics 191 (FIG. 4) receives and processes a magnetic field during at least some of the zero-voltage period 283 and the zero-voltage period 293 to produce an indicator signal indicating the presence of a metal within in the magnetic field generated by the transmit coil. This system is referred to herein as a voltage “symmetric bipolar system.” Both the first voltage 232 and the fourth voltage 238 may be provided from the first power source such that the switches switch the same voltage from first power source to the transmit coil as the first voltage and the fourth voltage in an opposite polarity sense. Similarly, both the second voltage 241 and the fifth voltage 235 maybe provided from the second power source such that the switches switch the same voltage from second power source to the transmit coil as the second voltage and the fifth voltage in an opposite polarity sense.

To compare the various systems to the conventional unipolar pulse induction equivalent low impedance drive disclosed in this invention, assume that the waveform 241, 232, 233 of period 281, 282, 283 is repeated twice within the fundamental period shown in FIG. 7, or alternatively, that this is identical to the waveform of FIG. 5 but two such waveforms occur in the same fundamental period as the fundamental period of the waveform of FIG. 7. This system half period of FIG. 5 waveform is referred to herein as a “half fundamental period unipolar system”. A

Assume the sequence of 235, 238, 239 of period 291, 292, 293 is a minor image about zero volts of the sequence 241, 232, 233, of period 281, 282, 283 so the bipolar waveform is symmetric, and the “fully symmetric bipolar system” is of the same fundamental period and the waveform is exactly fully symmetric.

A “full fundamental period unipolar system” may be defined with the fundamental period of the conventional unipolar pulse induction waveform (of FIG. 5) being the same as the “symmetric bipolar system” and “fully symmetric bipolar system,” but half the second voltage so that the transmit coil power dissipation is equivalent assuming a small transmit coil resistance. However, assume this resistance is infinitely small, and that the electronics is ideal.

Assume that the receive circuitry:
a. subtracts an average of the zero-voltage period 283 from an average of the zero-voltage period 293 for the “symmetric bipolar system”;
b. both the “half fundamental period unipolar system” and “full fundamental period unipolar system” receive circuits subtract an average of the first half of the zero-voltage period from an average of the second half of the zero-voltage period;
c. subtracts an average of one of the zero-voltage periods of the “fully symmetric bipolar system” period from an average of the other;
   so that any net “dc” signal from say moving the coil through the earth's magnetic field is cancelled in each case.

The “bipolar symmetric system” and the “fully symmetric bipolar system” and the “full fundamental period unipolar system” all have a signal gain advantage compared to the “half fundamental period unipolar system” of asymptotically approaching 4 times for very long time constant targets. However, both the “full fundamental period unipolar system” and the “fully symmetric bipolar system” have half the very short time constant gains compared to the “bipolar symmetric system” and the “half fundamental period unipolar system”. Hence, overall the “bipolar symmetric system” offers highest system gain. The electronics of an equivalent “bipolar symmetric system” conventional pulse induction system is relatively complex compared to the low impedance drive invention described herein, and also the low impedance drive offers the advantages described earlier.

The waveform in FIG. 7 can be provided by a different circuit for example such as the partial transmit switching circuit shown in FIG. 8. This circuit includes an “H bridge” switches 301, 302, 303, 304, 305, 306, to replace switches 155 and 156 in FIG. 4. This replacement can be inserted between points 170′, 176′ and 180′ in FIG. 4. Switches 301, 302, 303, 304, 305, 306 are controlled by control electronics 160 through extra control lines 311, 312, 313, 314. The transmit coil 151 current sensing resistor 152 is connected to the “Lo-side” switches 303 and 306. The “Hi-side” switches 301 and 302 are connected to the first power source at 170′. Control lines 311 and 312 act to connect coil 151 to the first power source in opposite polarity senses, and control lines 313 and 314 act to connect coil 151 to the second and third power source in opposite polarity senses. If either switches 303, 305, 166 and 159 are “on”, or switches 304, 306, 166 and 159 are “on,” then there is zero volts across the transmit coil and the transmit coil current may be measured by measuring the voltage across resistor 152 (plus the resistance of switch 159 if the voltage is measured relative to the system ground 153).

1. A metal detector used for detecting a metallic target including:
a) transmit electronics having a plurality of switches for generating a repeating transmit signal cycle, the repeating transmit signal cycle including at least one receive period and at least one non-zero transmit coil reactive voltage period;
b) a transmit coil having an inductance connected to the transmit electronics for receiving the repeating transmit signal cycle and generating a transmitted magnetic field;
c) a receive coil for receiving a received magnetic field during at least one receive period and providing a received signal induced by the received magnetic field;
d) at least one negative feedback loop for sensing a current in the transmit coil during at least one receive period to provide a control signal, the control signal controlling a magnitude and/or duration of the at least one non-zero transmit coil reactive voltage period such that the average value of the current during at least one receive period of every repeating transmit signal cycle is substantially constant, and the current during at least one receive period is substantially independent of the inductance of the transmit coil; and
e) receive electronics connected to the receive coil for processing the received signal during at least one receive period to produce an indicator output signal, the indicator output signal including a signal indicative of the presence of a metallic target in the soil.

2. A metal detector according to claim 1, wherein the repeating transmit signal cycle includes a high-voltage period, the high-voltage period is a non-zero transmit coil reactive voltage period, and is followed by a low-voltage period and at least another period of non-zero transmit coil reactive voltage period; the low-voltage period is the said receive period, and the average value of the transmit coil current during the low-voltage period of every repeating transmit signal cycle is non-zero.

3. A metal detector according to claim 1, wherein the repeating transmit signal cycle includes a low-voltage period, the low-voltage period followed by a high-voltage period, and the high-voltage period followed by a zero-voltage period; the zero-voltage period is the said receive period, and the average value of the transmit coil current during the zero-voltage period of every repeating transmit signal cycle is zero.

4. A metal detector according to claim 1, wherein the repeating transmit signal cycle includes at least two receive periods, a first receive period and a second receive period, the average value of the current during the first receive period is substantially different from the average value of the current during the second receive period.

5. A metal detector according to claim 4, wherein the repeating transmit signal cycle includes at least two different sequences, a first sequence and a second sequence, the first sequence including a first high-voltage period and a first low-voltage period, and the second sequence including a second high-voltage period and a second low-voltage period, wherein the first and second low-voltage periods are the first and second receive periods respectively, and the second sequence is opposite in polarity to the first sequence.

6. A metal detector according to claim 5 wherein the current waveform of the repeating transmit signal cycle is substantially a square wave.

7. A metal detector according to claim 1, wherein the repeating transmit signal cycle includes at least two different sequences, a first sequence and a second sequence, the first sequence including a first low-voltage period, a first high-voltage period and a first zero-voltage period, and the second sequence including a second low-voltage period, a second high-voltage period and a second zero-voltage period, wherein the first and second zero-voltage periods are first and second receive periods respectively, and at least one of the first low-voltage period, the first high-voltage period and the first zero-voltage period, differs from the respective second low-voltage period, second high-voltage period and second zero-voltage period in at least voltage and/or duration.

8. A metal detector according to claim 7, wherein the first low-voltage period is of opposite polarity to the second low-voltage period, and the first high-voltage period is of opposite polarity to the second high-voltage period.

9. A metal detector according to claim 1, wherein an output impedance of the transmit electronics connected to the transmit coil is less than three times an equivalent series resistance of the transmit coil at least immediately after the beginning of the receive period.

10. A metal detector according to claim 1 wherein the processing of the received signal by the receive electronics includes sampling and/or synchronous demodulation followed by averaging and/or low pass filtering to substantially remove signals with frequency of the repeating transmit signal cycle, to produce a receive reactive signal and a receive resistive signal, the receive reactive signal being responsive to non-dissipative components coupling between the transmit magnetic field and the receive magnetic field, and the receive resistive signal being responsive to dissipative components coupling between the transmit magnetic field and the receive magnetic field,
wherein the receive reactive signal is differentiated with respect to time to give a differentiated receive reactive signal; a first portion of the differentiated receive reactive signal is subtracted from the receive resistive signal to give a modified receive resistive signal, the said first portion is selected to approximately cancel any component of the receive resistive signal proportional to the differentiated receive reactive signal; and the modified receive resistive signal is further processed by the receive electronics to produce an indicator signal.

11. A metal detector according to claim 2, wherein the absolute average voltage value across the transmit coil of the high-voltage period is at least about three times an absolute average voltage value across the transmit coil of the low-voltage period.

12. A metal detector according to claim 2, wherein the average absolute value of a voltage during a high-voltage period is within the range of about 10 volts to about 400 volts.

13. A metal detector according to claim 2, wherein the average absolute value of a voltage during a low-voltage period is within the range of about 0.1 volts to about 15 volts.
